(19) United States
(12) Patent Application Publication
(10) Pub. No.: US 2012/0000337 A1
(43) Pub. Date: Jan. 5, 2012

(54) ASSEMBLY AND METHOD FOR IMPROVED SINGULATION

(75) Inventors: Xue Fang Shen, Singapore (SG); Jing Zhang, Singapore (SG)

(73) Assignee: Rokko Technology Pte Ltd., Singapore (SG)

(21) Appl. No.: 13/254,781

(22) PCT Filed: Mar. 4, 2010
(86) PCT No.: PCT/SG2010/000075

§ 371 Date: Sep. 2, 2011

(30) Foreign Application Priority Data
Mar. 5, 2009 (SG) 200901594-2

(51) Int. Cl. H01L 21/78; B21D 28/00

(52) U.S. Cl. 83/821; 83/684

(57) ABSTRACT

A punch and die assembly for singulating an IC unit from a substrate, the assembly comprising an array of punches a guide block having opposed first and second faces with a plurality of elongate channels corresponding to each punch extending from said first to second face; a die block for supporting said substrate, said die block having an array of punching zones at which the punches bear so as to singulate all or a portion of a peripheral edge of said IC units from the substrate.

### FIELD OF THE INVENTION

The invention relates to the singulation of IC units from a substrate of said units. In particular the invention relates to punching as the means of singulation.

### BACKGROUND OF THE INVENTION

Singulation of IC units from a substrate in an efficient manner involves maximizing the rate of singulation of the units at an acceptable capital cost. One method of singulation includes punching the units from the substrate, i.e. applying a shearing force to the face of the substrate so as to cut all or portion of the peripheral edge of each unit. Given the size of the singulated units and the need to maintain a clean cut edge of said units, the tolerance required is extremely high, and typically in the range 2 to 5 μm.

Further, punch and die assemblies, because of the high tolerance and the nature of the singulation tend not to have long operational lives because of damage to the assembly as the punch contacts the die.

There is therefore an ongoing need to improve the quality of the product produced by the punch and die assembly whilst maximizing the life of the punch and die assembly and so minimizing capital cost through minimizing replacement.

### SUMMARY OF THE INVENTION

In the first aspect the invention provides a punch and die assembly for singulating an IC unit from a substrate, the assembly comprising an array of punches a guide block having opposed first and second faces with a plurality of elongate channels corresponding to each punch extending from said first to second face; a die block for supporting said substrate, said die block having an array of punching zones at which the punches bear so as to singulate all or a portion of a peripheral edge of said IC units from the substrate.

In a second aspect the invention provides a guide block for use with a punch and die assembly for singulating an IC unit from a substrate, the guide assembly comprising opposed first and second faces with a plurality of elongate channels each corresponding to a punch extending from said first to second face.

Whilst considerable effort has been made in the past to prevent the introduction of errors into the process, nevertheless, other aspects can contribute to the overall tolerance of the assembly causing an accumulated error in the final product.

An important introduction of error into the process is the use of guide blocks, often referred to as “strippers”, which do not fully restrain the upper portion of the punches. A great deal of effort in the prior art has been placed on tolerances at the punching end of each punch and the die. However, the guide assembly tends to be overlooked but can lead to a high degree of error. In the present invention providing a channel through the guide block so as to restrain the punch for a significant portion of the travel of the punch reduces both translation and rotation error in the punch.

In addition to the elongate channels provided in the guide block, the present invention may further include several embodiments aimed at addressing deficiencies in the prior art that in some amount to an accumulated error which shortens the effective life of the punch and die assembly as well as limits the ability of the assembly to provide high quality output.

For instance in one embodiment, the present invention may further include an inclined inside face on the channel. By inclining one face to the vertical, the punch on traveling through the channel may be directed away from the leading edge of the die. A significant problem in the longevity of prior art punch and die assemblies is cracking of the die block caused by repeated contact between the punch and the die. By providing an inclined face within the channel, the punch may be directed away from a leading edge of the die by, a specified amount and so avoid said contact. It follows that by avoiding contact, the assembly's longevity may be increased.

Alternatively the inside face of the channel may be offset such that the punch may still move in a vertically reciprocal action but be intentionally directed away from a leading edge by a specified amount. Because of the high degree of tolerance in the machining of the components of the assembly, the specified amount offset may still provide a high quality result but also avoid a debilitating contact.

### BRIEF DESCRIPTION OF DRAWINGS

It will be convenient to further describe the present invention with respect to the accompanying drawings that illustrate possible arrangements of the invention. Other arrangements of the invention are possible and consequently the particularity of the accompanying drawing is not to be understood as superseding the generality of the preceding description of the invention.

FIG. 1 is a plan view of a punch table according to one embodiment of the present invention;

FIGS. 2A to 8A are various views of a Y oriented punch and die assembly according to one embodiment of the present invention;

FIGS. 2B to 8B are various views of an X oriented punch and die assembly according to a further embodiment of the present invention;

FIG. 9 is a detailed view of a punch according to a further embodiment of the present invention and;

FIG. 10 is a plan view of a punch according to a still further embodiment of the present invention.

### DETAILED DESCRIPTION

The singulation of IC units and in particular the punching of said IC units as the means of singulation requires a particularly high tolerance such as in the range 2 to 5 μm. Where punch and die assemblies of the prior art have failed is not sufficiently addressing the effect of an accumulated error, that is the cumulative effect of each component contributes to the overall error in the process.

The first of these errors involves insufficient use of the guide block to guide the movement of the punch as it impacts against the die. Further errors in the flexibility and assembled tolerance are also major contributors, by providing key components as assemblies in themselves rather than a unitary block.

The present invention seeks to address these problems as the core invention and individual issues as various embodiments. Accordingly the invention provides for a guide block having a plurality of elongate channels with each channel extending through the guide block and through which each individual punch travels.

Whilst guide blocks may be used in the prior art, the aperture through which the punch travels is often too short and so allowing rotation about the aperture of the punch to provide a degree of movement or flexibility of the punch itself. By providing a full length channel through the full thickness of the guide block, greater control of the punch may be provided and so a reduction in the contribution of error such movement provides.

Elongate in this instance will to a degree be qualitative in that the length of the channel will be sufficient to limit undue movement of the punch within the channel. For instance rotational deflection of the punch will be more prevalent as the channel shortens. The skilled person will appreciate that within the tolerances of manufacture, an acceptable rotational deflection of the punch will depend on the actual tolerance and so a prescriptive length of the channel is unnecessary for the skilled person to make a determination as to what will be sufficient.

In one embodiment, however, the channel will be of a length equal to or in excess of the major cross sectional dimension of the punch. For instance, for a punch being 1 mm thick and 9 mm wide, in one embodiment the length of the elongate channel may be equal to or in excess of 9 mm. Thus in one sense the aspect ratio between the elongate channel length and the punch width may be greater than or equal to one.

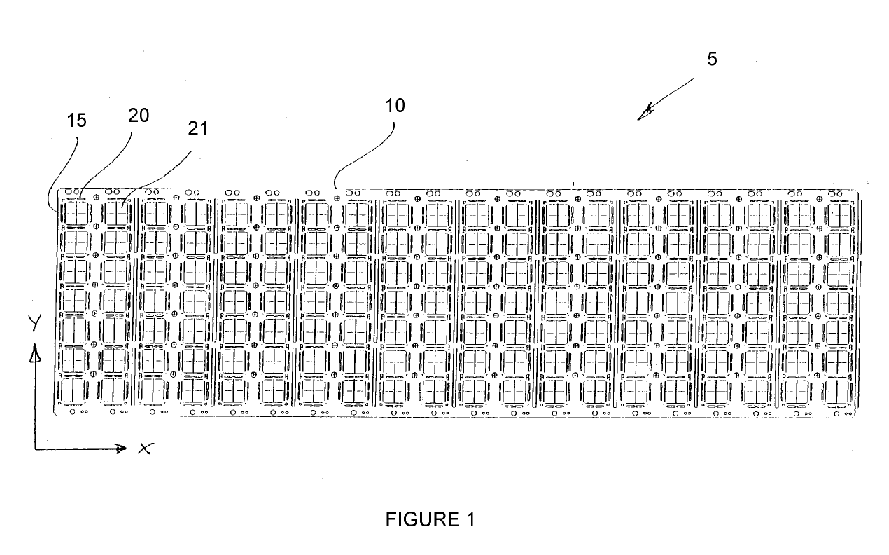

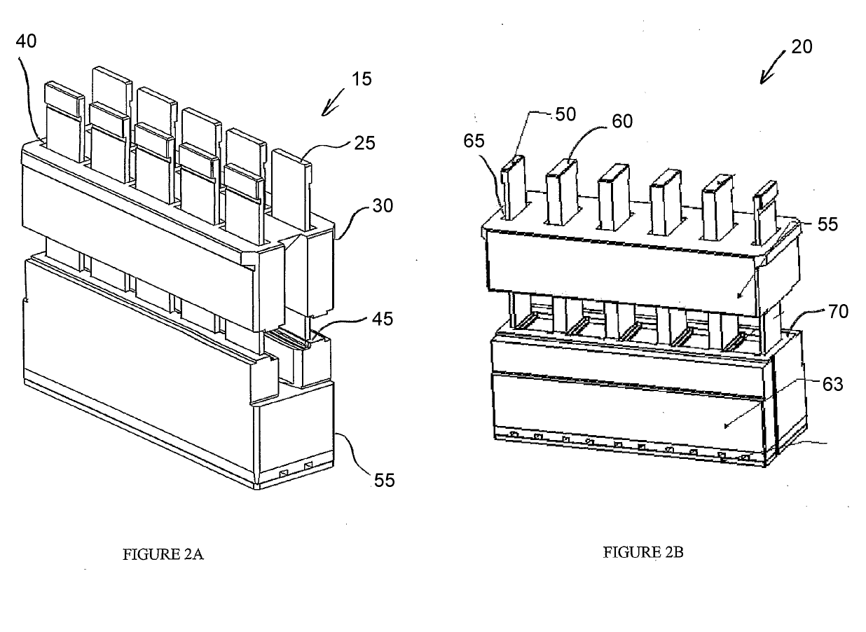

FIG. 1 shows a plan view of a punch table 5 comprising a block 10 upon which a substrate may be placed. IC unit zones 21 correspond to the cutting zone provided by the Y oriented punches 15 and the X oriented punches 20. FIGS. 2A to 8A show detailed views of the Y oriented punches 15 with FIGS. 2B to 813 showing the X oriented punches 20.

Considering first the Y punch and die assembly 15 as shown in FIG. 2A, the assembly 15 includes a guide block 30 often known as a “stripper” having a plurality of elongate channels 40 which pass through the guide block 30. These channels 40 are arranged to encompass punches 25 for the full width of the guide block 30 as compared to those of the prior art having a mere aperture. A key characteristic of guide blocks of the prior art is the tendency for a very short guide path provided by an aperture to allow movement of the punch according to the tolerances of the punch and aperture. It follows that an aperture machined to the same tolerance as that of an elongate channel encompassing a punch will allow an angular deflection of the punch greater than that of the elongate channel. The longer the path through which the punch is guided, the smaller will be the angular deflection for which the punch will be permitted.

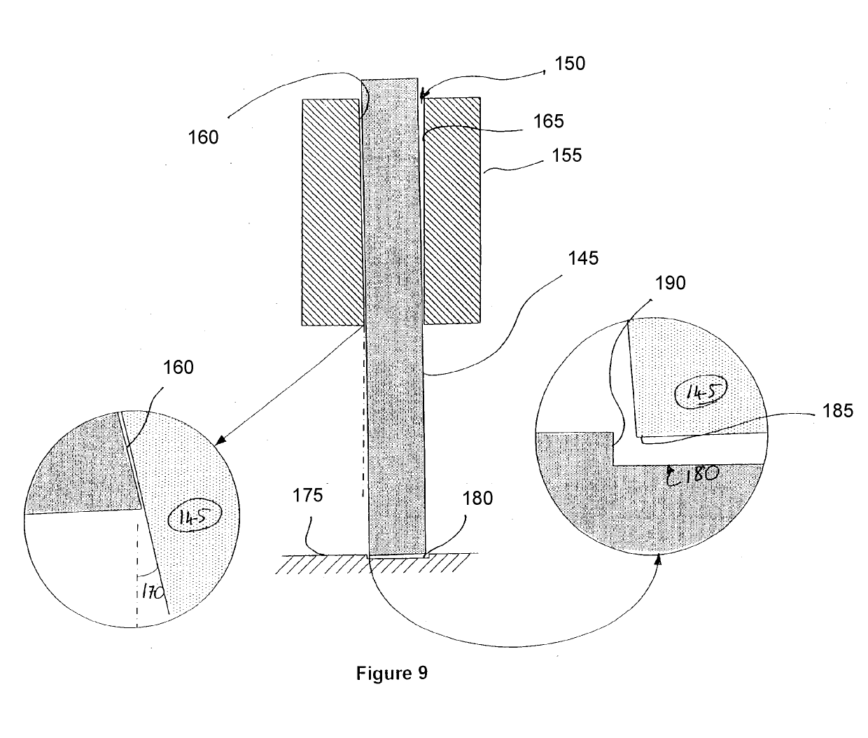

A punch of the type being considered may be specific for QFN packages. It may have a width of about 9 mm and machined to a tolerance of for instance 2 to 5 μm. The punch may also have a width of about 1 mm and machined to a tolerance in the range of 1 to 5 μm. Accordingly the channels 40 through which the punch passes through the guide block 30 may be machined to a similar tolerance. In an alternative arrangement one side of the channel may be machined to a lower tolerance for instance up to 10 μm with the remaining faces of the rectangular channel in the range 1 to 5 μm. This looser fit on one side of the channel may tend to allow the punch to “swing” towards the looser tolerance on punching. The benefits of such a looser tolerance on one side will be discussed later and in particular to the arrangement shown in FIG. 9.

The punch 25 passes through the channel 40 of the guide block 30 and impacts against a die 45 supported by a die block 35.

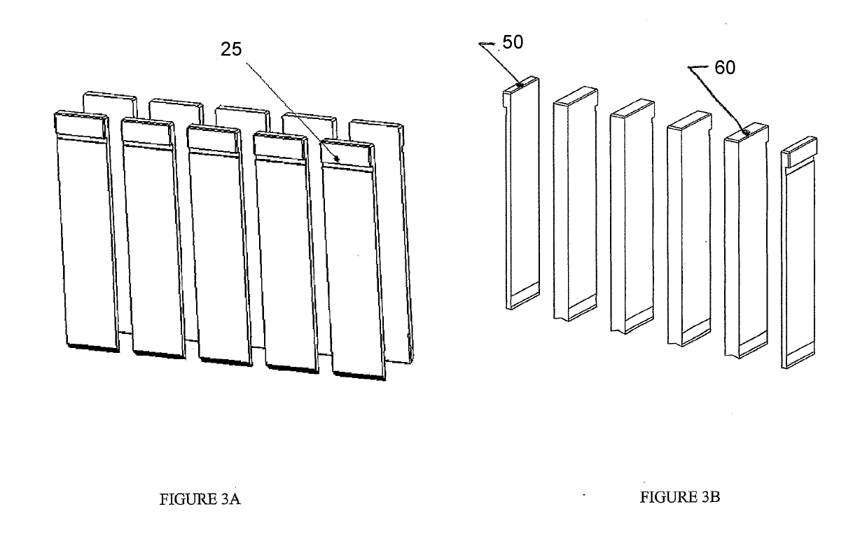

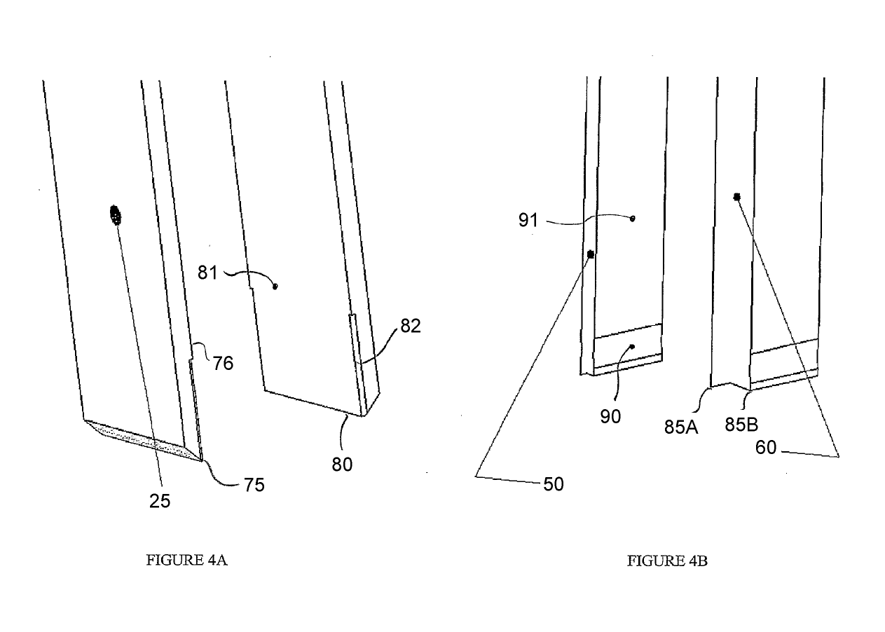

Returning to the punches, FIGS. 3A and 4A show detailed view of the 5×2 array of punches. It will be noted that the punch as a bevel cutting edge 75, 80. The Y oriented punch 25 is arranged to cut opposed edges of the IC unit and so the array is formed as a series of punch pairs. In this embodiment there are five pairs cutting the opposed edges of the IC unit with the beveled edges 75, 80 having the longer cutting faces 76, 81 facing each other so as to provide a clean cut. It will be appreciated that the Y punch and die assembly 15 may have considerably more than five pairs of punches or in fact may have less subject to the intended application.

The punches have on vertical edges on either side of the cutting face 81 chamfers 82 cut from the edge and projecting from the cutting edge 80 to a predetermined distance from the cutting edge. This distance will be the subject of trial but may be approximately equal to the punch width. These chamfers tend to reduce friction by separating the edge from other portions of the assembly 15 and consequently adding to the longevity of the individual punches and the punch and die assembly 15 overall.

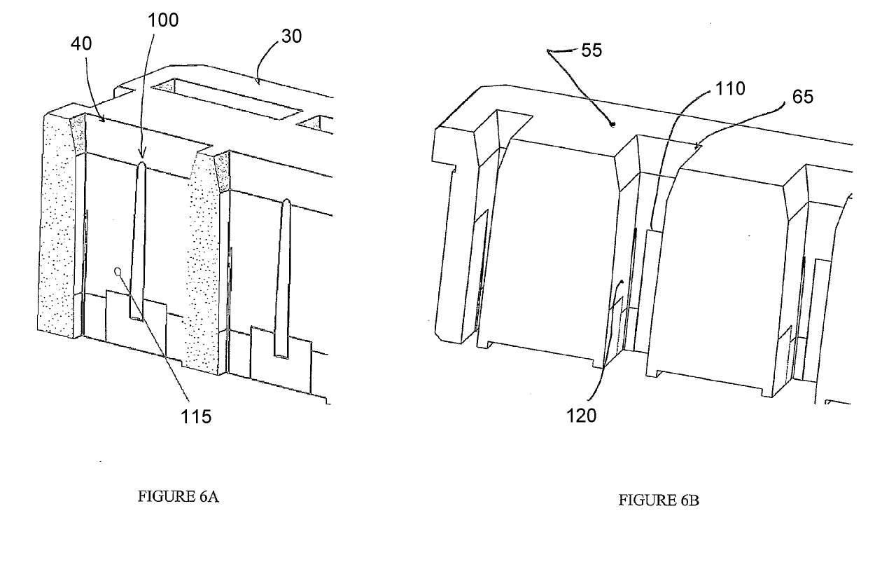

Returning to the guide block 30 having the array of elongate channels 40 corresponding to their required arrangement of the punches 25. In particular FIG. 6A shows a section view of the channel 40 having a flared opening to facilitate placement of the punch. It will be noted along one face 115 that a groove 100 has been machined into the face 115. This groove 100 acts as an air vent such that on driving the punch 25 downwards, one face 115 of the channel 40 permits a flow of air upwards. This air vent 100 promotes an air layer between the punch and the channel 40 providing numerous benefits. The air layer may reduces friction and therefore promote a longer working life of the assembly 15. The air vent may also act in a similar manner or in conjunction with the looser tolerance on that face so as to provide a clearance in which to bias the punch to “swing” towards that end. Further benefits may include self cleaning. Detritus resulting from the punching process may be provided a path to escape along the air vent. Further still the flow of air may provide a cooling effect, again adding to the longevity of the punch and punch and die assembly.

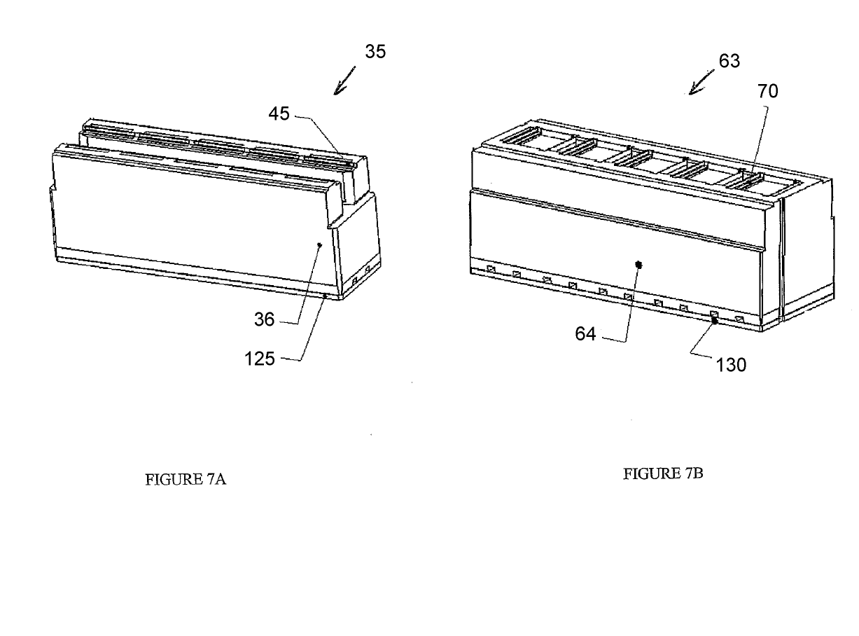

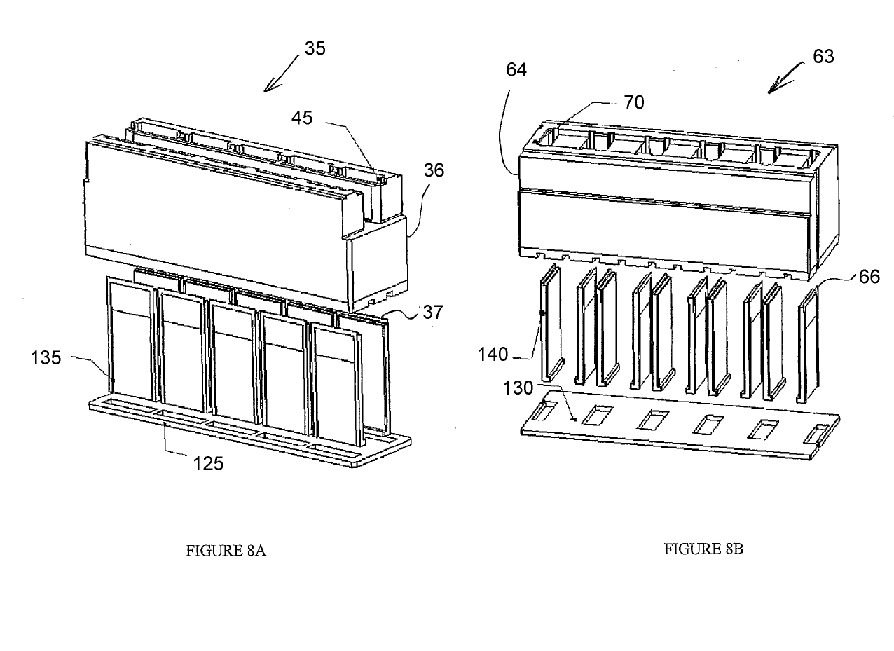

FIGS. 7A and 8A show a die block 35 for the Y punch and die assembly 15. The die block 35 is itself an assembly comprising an anvil 36 having a plurality of slots into which die inserts fit. The die 45 includes an upper cutting portion 37 which projects up through the anvil 36 to provide a seat upon which the substrate lies for punching. The punch descends on the substrate and bears against the die 45 with the die insert 135 acting as a cutting edge beneath. The die inserts 135 are held in place by a shim 125 and so maintaining the inserts in an assembly arrangement. The alternative practice according to the prior art is to have a full assembly whereby the anvil 36 is replaced by a series of members which combine to form the entire die block. It will be appreciated that every connection between members adds to the overall error through combining tolerances of machine surfaces. Thus providing an assembly for the die block further accumulates error in the punching process. The present invention avoids this by providing a unitary anvil 36 which still has the benefits of an assembly through providing a shim 125 holding the die inserts 135 in place.

The X punch and die assembly shown in FIGS. 2B to 8B demonstrates similar advantages to the Y punch and die assembly 15 but with accommodation for the orientation directed to the X axes. Therefore as shown in FIG. 2B, an X punch and die assembly 20 includes a plurality of punches 50, 60 movable within a guide block 55 through elongate channels 65. The channels 65 extend through the full thickness of the guide block 55 so as to control angular deflection and so produce introduced error.

As will be seen from FIG. 1, the integrated circuit units within the substrate are oriented such that adjacent units along the X axes are extremely close as compared to adjacent units along the Y axes. Accordingly accommodation must be made for the X punch and die assembly 20 to be able to accurately and efficiently punch the IC units whilst not adversely affecting adjacent units. To this end, the X punches 60 include a double edge as seen in FIGS. 3B and 4B whereby the two edges 85A, 85B correspond to adjacent IC units so as to cut the adjacent edges simultaneously. Because the X punch and die assembly 20 has an array of X punches for a finite distance, the punches 50 at extreme ends of the assembly 20 need only punch one edge and therefore are considerably smaller than that of the internal X punches 60.

FIG. 4B shows a different means of reducing friction and extending the life of the punches. Provided in a face 91 of the punch is a recess 90 adjacent to the cutting edges of the punch 50, 60. The recess is provided on both sides of the punch and acts to reduce friction between the punch and die leading to improved life of the punch. The reduced friction further increases the life of the die. Apart from having to face 91 recede from the die, the inclusion of the recess may trap air and further assist in providing an air path during movement of the punch and so facilitating the reduction in friction.

It will be appreciated that the recess 90 for the X punch and the chamfer 82 for the Y punch may be used interchangeably between the X and Y punches and also used together to provide an additional benefit.

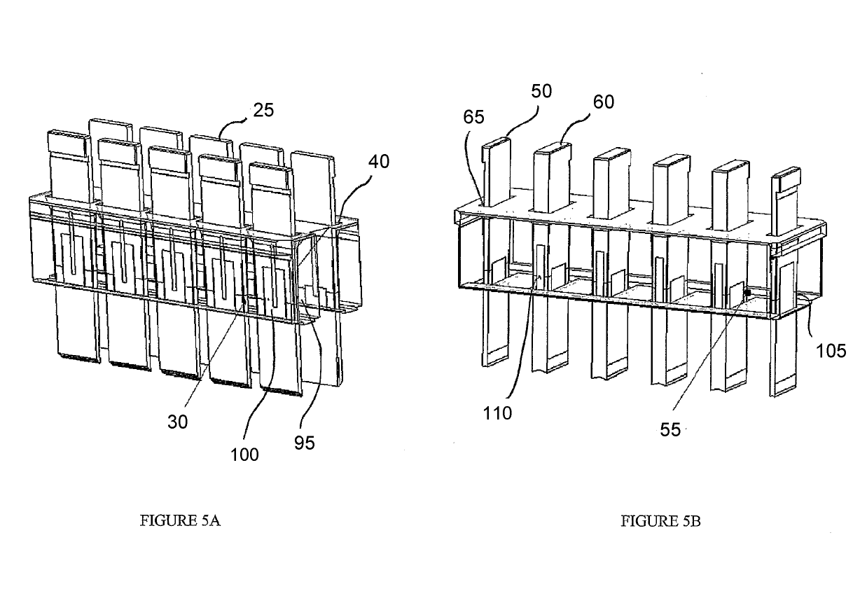

FIG. 5B shows the guide block 55 for the X punch and die assembly 20. The transparent guide block 55 shows the position of the punches 50, 60 through the channels 65 which as discussed, provide for a greater control over the punch and so a reduction in accumulated error.

An additional benefit of providing elongate channels through the guide block is the thickness of the walls surrounding the punch. They will tend to be thicker and so possibly less prone to warping and deformation during the application of load. Thus a degree of rigidity of the guide block provided by thicker walls may provide advantage over the prior art.

FIGS. 7B and 8B show a similar die block 65 arrangement to that of the Y die block 35. Here an anvil 64 is provided with slots through which die inserts 140 are inserted to provide a seat against which the substrate is cut. The die inserts include a cutting edge 66 to assist in the cutting process with the die inserts 140 held securely in place by a shim 130. As with the Y die block 35, the X die block 63 avoids the accumulated error of an assembly through providing a one piece anvil 64 to contain the inserts and so further providing advantage over the prior art.

A significant limitation on the effective life of a punch and die assembly is the longevity of the die. Typically 10,000 cycles is an expected lifetime of a die before cracking of the die occurs or stress build up through friction causes jamming of the punches. With regard to cracking of the die block, a significant cause of this is the impact between the punches and the edge of the die on a repeated basis. This is a difficult problem to avoid. The alignment of the guide block and die needs to ensure that a 2 to 5 μm tolerance can be maintained for the punch to avoid contact with the edge of the die. FIG. 9 shows one embodiment of the present invention which addresses this problem. In this embodiment a punch 145 passes through a channel 150 of a guide block 155. The punch 145 is aligned with a die block 175 and in particular a die seat 180, or punching zone in which the IC unit (not shown). In this embodiment the guide block 155 provides a variation in the alignment which ensures contact is avoided between the die and the punch. Because the components are still manufactured to a high tolerance such as in the range 2 to 5 μm, error is not introduced but contact is avoided. In this embodiment the channel 150 of the guide block 155 has an internal face 160 on one side of the punch 145. This face 160 is inclined at an angle 170 to the vertical, and so defining an inclined path along which the punch travels. The inclined path is determined such that the punch, and in particular the cutting edge diverges from contact with a peripheral, or leading, edge 185 and so misses the leading edge 190 of the die. Consequently the die edge and punch do not contact and as a result cracking of the die is avoided. Such avoidance of contact whilst not affecting the quality of the punched product may yield an effective life of 100,000 cycles or more.

In an alternative embodiment, not shown, the internal face of the guide block channel may remain vertical offset by a known distance. For instance 5 μm such that the punch continues to move in a vertical reciprocal motion but is offset from the edge of the die by a sufficient distance to ensure contact is avoided.

In this embodiment the opposed face 165 of the channel may be machined to a lower tolerance such as for instance 10 μm. This has the further advantage of “swinging” the punch generally in the direction of the looser tolerance face 165. It has been found this “swinging” effect shifts the impact stresses from the leading edge 190 of the die towards the opposed ends. By providing a looser tolerance also for the die impact issues are still avoided and so stress dissipated by this “swinging” effect.

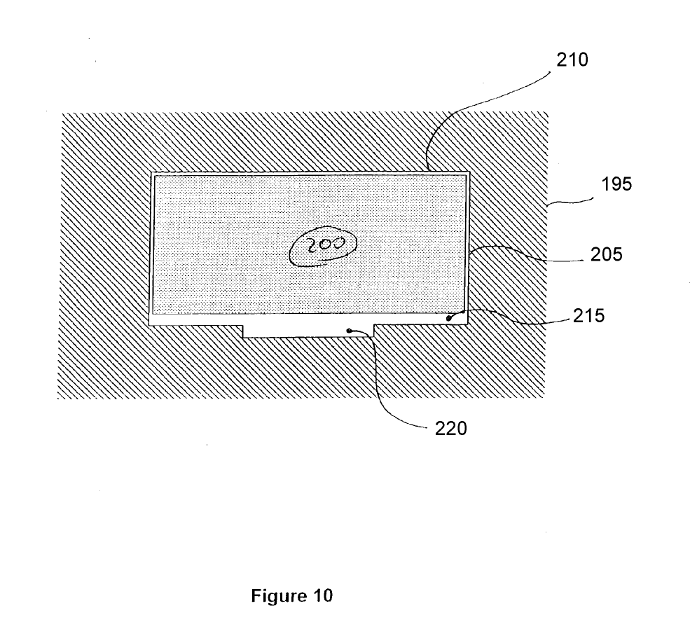

FIG. 10 shows a plan view of a punch 200 within a channel 210 of a guide block 195. In this plan view, a rectangular air vent 220 is provided in one face 215 of the channel. This air vent provides for a flow upwards of air through the vent 220 as the punch is directed downwards providing an air layer which assists with friction cooling and possibly self cleaning. Further by machining the air vent face 215 at a looser tolerance such as about 10 μm as compared to the other faces 205, 210 which may be machined to tolerances in the range 2 to 5 μm may also lead to the “swinging” effect as previously described.

1. A punch and die assembly for singulating an IC unit from a substrate, the assembly comprising:
an array of punches;
a guide block having opposed first and second faces with a plurality of elongate channels corresponding to each punch extending from said first to second face; and
a die block for supporting said substrate, said die block having an array of punching zones at which the punches bear so as to singulate all or a portion of a peripheral edge of said IC units from the substrate.

2. The punch and die assembly according to claim 1, wherein each of said channels have an internal surface inclined to the vertical axis such that a path followed by said punches are also inclined from the vertical.

3. The punch and die assembly according to claim 2, wherein the inclined path is arranged such that a cutting edge of each of said punches diverges from contact with at least one peripheral edge of the corresponding punching zone.

4. The punch and die assembly according to claim 1, wherein said assembly has a longitudinal axis parallel to the cutting edge of said punches.

5. The punch and die assembly according to claim 1, wherein said assembly has a longitudinal axis at right angles to the cutting edge of said punches.

6. The punch and die assembly according to claim 5, wherein said punches include two cutting edges for punching peripheral edges of adjacent IC units within said substrate.

7. The punch and die assembly according to claim 1, wherein said punches include a profiled portion adjacent to the cutting edge, said profile portion providing a reduction in friction between said punch and die during said punching action.

8. The punch and die assembly according to claim 1, wherein said channels include an internal face having a longitudinal recess removed therefrom so as to facilitate the movement of air upwards as the punch is moving downwards.

9. The punch and die assembly according to claim 2, wherein said inclined surface is on an opposed side of the channel to the face having the longitudinal recess.

10. The assembly according to claim 1, wherein said die block is machined from a single member.

11. The punch and die assembly according to claim 10, wherein said die block further includes inserts having a cutting edge so as to form a seat upon which to facilitate the punching of said IC units.

12. A guide block for use with a punch and die assembly for singulating an IC unit from a substrate, the guide assembly comprising:
opposed first and second faces with a plurality of elongate channels each corresponding to a punch extending from said first to second face.

13. The guide assembly according to claim 12, further comprising:
an array of punches;
a guide block having opposed first and second faces with a plurality of elongate channels corresponding to each punch extending from said first to second face; and
a die block for supporting said substrate, said die block having an array of punching zones at which the punches bear so as to singulate all or a portion of a peripheral edge of said IC units from the substrate.
